(19) United States
(12) Patent Application Publication
(10) Pub. No.: US 2011/0259401 A1
(43) Pub. Date: Oct. 27, 2011

(54) COMPONENT AND USE OF A COMPONENT

(76) Inventor: Christoph Bathon, Glattbach (DE)

(21) Appl. No.: 13/126,755

(22) PCT Filed: Mar. 30, 2009
(86) PCT No.: PCT/DE2009/000402

§ 371 Date: Jul. 18, 2011

(30) Foreign Application Priority Data
Oct. 28, 2008 (DE) 20 2008 014 320.9

(51) Int. Cl. H01L 31/058; F24J 2/04

(52) U.S. Cl. 136/248; 126/634

(57) ABSTRACT

The invention relates to a component for a construction, said component comprising at least one wood-retainer composite element (I) consisting of at least one wood element (2) and one retainer (III), the wood element (2) and the retainer (III) being connected in an essentially non-positively engaged and/or form-fitting and/or integrally bonding manner. The wood element (2) and the retainer (III) are at least partially connected by thrust force. At least one solar element, especially a heliothermal element (5), is integrated into the retainer (3) and/or a photovoltaic element (6) is arranged on a side (7) of the retainer (III) facing the light. The photovoltaic element is especially at least partially hydrophobic.

The invention relates to a component for a construction, said component comprising at least a wood-retaining means composite element.

The invention DE 197 00 873 describes a construction element for the connection of flat-shaped components, in particular of solar modules and solar collectors above a roof. The base, i.e. the actually carrying element is, for example, the roof skin, on which this energy-generating element is fastened.

The invention DE 200 10 299 shows a facade structure and/or light roof structure and assembly device for fastening of solar collectors at a facade structure and/or light roof structure.

The invention DE 20 in 2008 003 148 describes an arrangement of several solar collectors by a supporting rack which permits lining up of several regularly arranged flat solar collectors.

It is unfavorable in the state of the art that known solar heat systems or photovoltaic systems are put on merely as an additional, energy generating component on other structures, in particular as solar collectors arranged on the roof.

The problem of the present invention is to provide a component which allows an easy and at the same time stable construction for the production of solar power.

The problem is solved by a Component for a construction, said component comprising at least one wood-retaining means-composite element, with at least one wooden element and one retaining means, in which the connection of the wooden element and the retaining means among each other is essentially composed force-fit and/or form-fit and/or in an integrally bonding manner, especially the wooden element and the retaining means element are at least partially connected by thrust force, whereas at least one solar element, especially a solar heat element, is integrated in combination with the retaining means element and/or a photovoltaic element is arranged on a light facing side of the retaining means, whereas the photovoltaic element is especially built at least partially water-repellent.

The invention delivers an energy-generating, weight-bearing hybrid component which comprises a bearing element as a wooden-retaining means-composite component with energy-generating solar heat element and/or photo-voltaic element. The invention enables therefore to provide a multifunctional component which unites energy-generating and statically weight-bearing elements. Thereby current is generated by the solar irradiation by the photo-voltaic elements and at the same time the solar heat elements, which are integrated behind the first elements in the weight-bearing concrete as wood-retaining means composite elements, are warmed up. The solar heat elements, which are integrated in the weight-bearing concrete, guide the warmed up liquid to the respective house technology. A mechanical contact to the other components can be carried out in an easy manner by strength forwarding through the wood element and/or through strength forwarding through the concrete element. With the help of the solar elements the production of heat can be caused on the one hand and a transport of the warm water in the household at the same time a part of the energy generated by the photo-voltaic can be used for the cooling of the building within pipelines of a concrete element arranged respectively in the component.

Therefore a weight-bearing wood-retaining means-composite component is used for the utilization of the solar energy for the purposes of the solar heat and/or photo-voltaic. By this the growing raw material wood ,which is also produced by solar energy, becomes a weight-bearing element in this wood-retaining means-solar-element.

It is advantageous, if the wooden element and the retaining means are interconnected in that way, that a zone is generated, which at least has a solar element, especially a solar heat element.

It is advantageous, if the zone is at least partially coated with a means, that is especially heat conducting and/or light absorbing, especially made of a mineral material, especially mud, clay, light-weight concrete and/or concrete.

It is advantageous, if the zone has a substantially thermo insulating insulation at a not light facing side.

It is advantageous, if the zone is coated at a light facing side with a photovoltaic element, that is at least partially thermo conducting and/or light transmissive.

It is advantageous, if the retaining means has concrete and/or wood and/or metal and/or plastics.

It is advantageous, if the wood-retaining means-composite element has at least one wood-concrete-composite element, with at least one wooden element and a concrete element substantially in the form of a concrete plate, whereas the connection of the wooden element and of the concrete element among each other is composed force-fit and/or form-fit and/or in an integrally bonding manner, especially the wooden element and the concrete element are connected by thrust force, whereas at least one solar element, especially a solar heat element, is integrated in the concrete element and/or a photovoltaic element is arranged on a light facing side of the concrete element.

It is advantageous, if the composite element has a wooden element and at least two concrete elements, whereas the wooden element is connected force-fitting and/or form-fitting and/or in an integrally bonding manner to the two concrete elements as an intermediate element and that at least one solar heat element is integrated into the relatively to the direction of the light incidence outermost concrete element and/or a cooling element is integrated into the innermost concrete element.

It is advantageous, if the composite element has at least two wooden elements and an intermediate concrete element, whereas the connection between the wooden element and the concrete element is force-fit and/or form-fit and/or in an integrally bonding manner.

It is advantageous, if beneath the photovoltaic element a space for ventilation is provided.

It is advantageous, if the connection between the wooden element and the retainer element (III) has a geometric form fitting and or a mechanical connection means and/or a glue connection, especially with bars, tubes, lattices and/or grids and/or a surface bonded joint and/or a welding connection and/or concrete casting, whereas the connection is especially a push-firm connection, in particular by mechanical connecting means, in particular by nails, screws and/or brads.

It is advantageous, if the composite elements are at least partially prefabricated and are brought together in the plant and/or on the building site.

It is advantageous, if the wooden elements comprise one-piece cross sections, in particular in the form of beams, chevrons, binders, panels, discs, planks and/or multi partial cross sections, in particular sceleton framings, triangle bar carriers, I-form beams, T-form carriers, case carriers and/or ligament panels.

It is advantageous, if the concrete elements comprise one-piece cross sections in particular in form of beams, bearings, panels, discs and/or multi partial cross sections, in particular in the form of TT-bearings, I-bearings, T-bearings, case bearings, ligament panels, IF panels.

It is advantageous, if the composite element is provided with damming up, isolating, protecting and/or dressing materials and introduced in particular between wooden elements, insulations and/or installations in the plane and/or on the building site, so that this offers a thermal isolation to the concrete, in particular with an inside-recumbent, final wall element, in particular as a steam barrier, in particular from plaster boards.

It is advantageous, if the wood-retainer means-composite element has at least one wood-wood-composite element, with at least a first wooden element and a second wooden element substantially in the form of a connection rob, which is applied on the first wooden element and which defines at least partially a hollow space together with the first wooden element, the hollow space is coated with a solar element, especially a solar heat element.

It is advantageous, if the wood-retainer means-composite element has at least a wood-metal and/or plastics-composite element, with at least one wooden element and a metal and/or plastics bar, which is provided on the wooden element and together with the wooden element defines at least partially a zone, which is coated with a solar element, especially a solar heat element.

Use of a component according to one of the claims 1 to 17 for constructions like buildings, apartment houses, trade constructions, industrial constructions, sports facilities, factories, parking houses, stadiums, towers, bridges, noise barriers, car ports, in particular for building coverings, roofs, walls, facades.

Use of a component of one of the claims 1 to 17 for constructions like stand-alone solar arrangements, in particular in solar parks, in particular in stooped in particular parabolic form of the wood-retainer means-composite elements.

Other features and advantages of the invention arise from the claims and the following description in which implementation examples of the object of the invention are explained in connection with the drawings.

Showing:

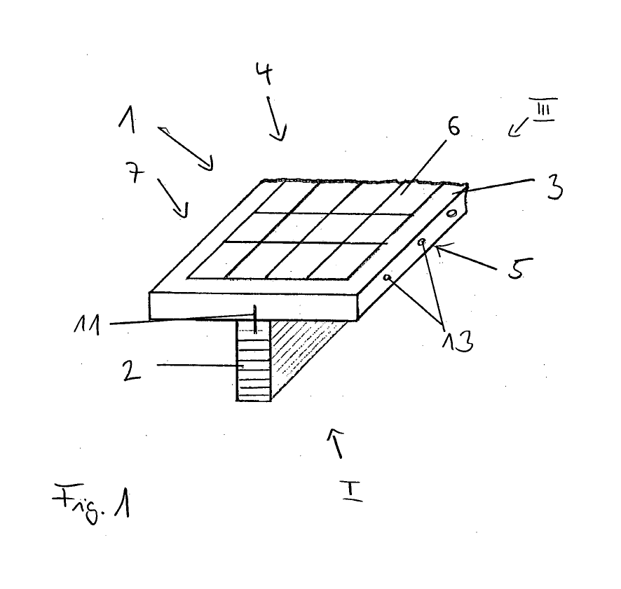

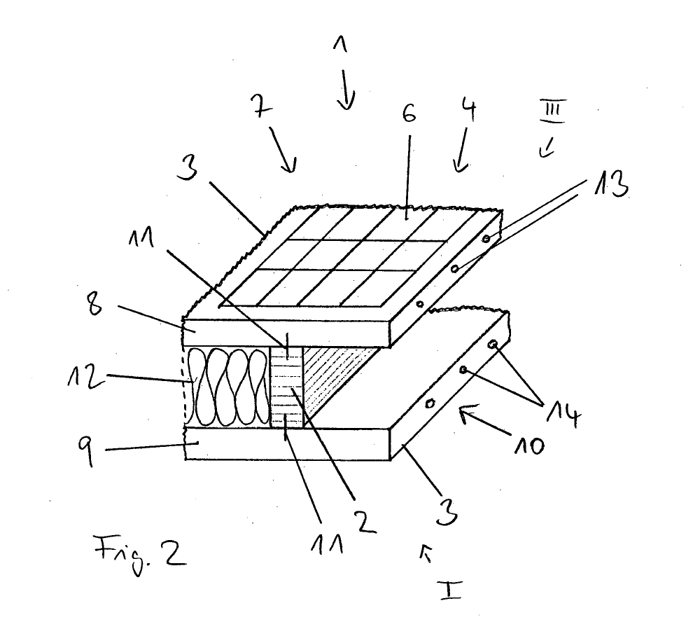

FIG. 1 a component according to the invention,

FIG. 2 a component according to the invention with two concrete elements and

FIG. 3 a component according to the invention as a solar arrangement.

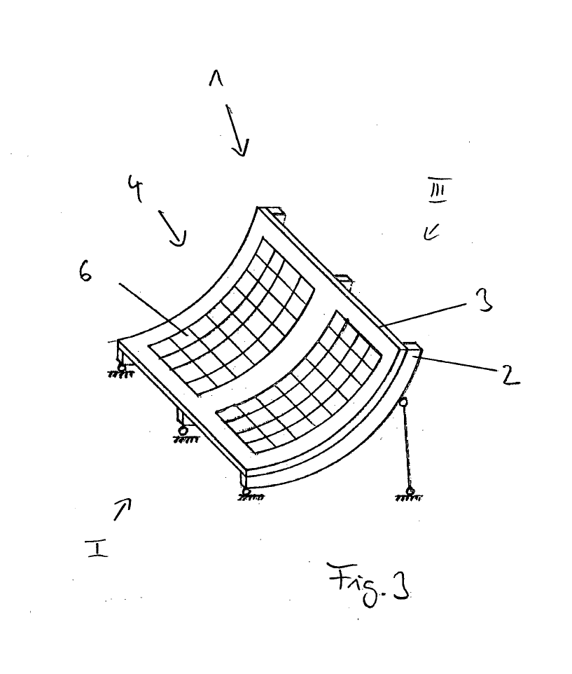

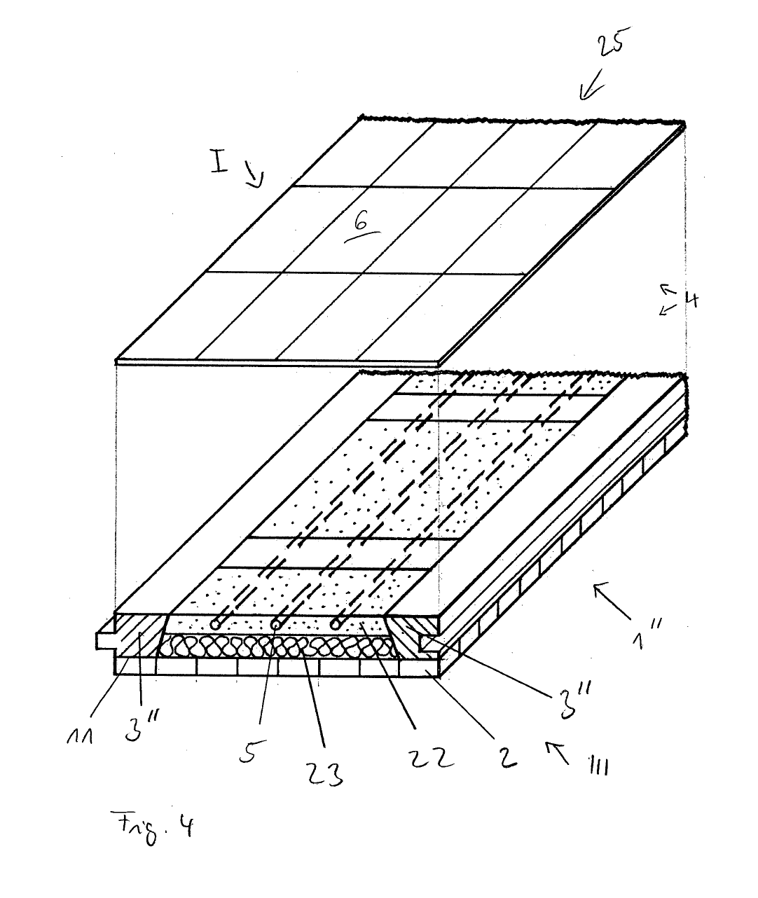

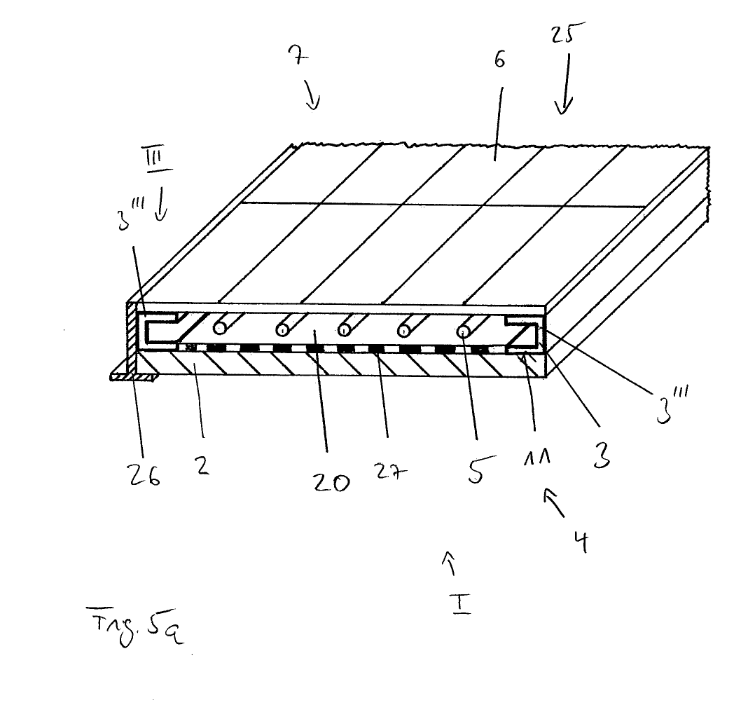

FIG. 4 a component according to the invention with two wooden elements,

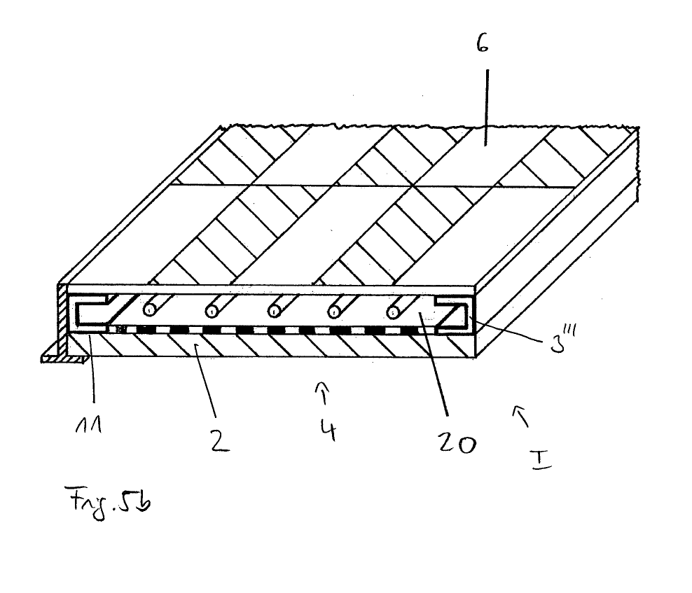

FIG. 5a a component according to the invention with a metal element or a plastics element,

FIG. 5b a component according to the invention with a metal element and/or a plastic element, and

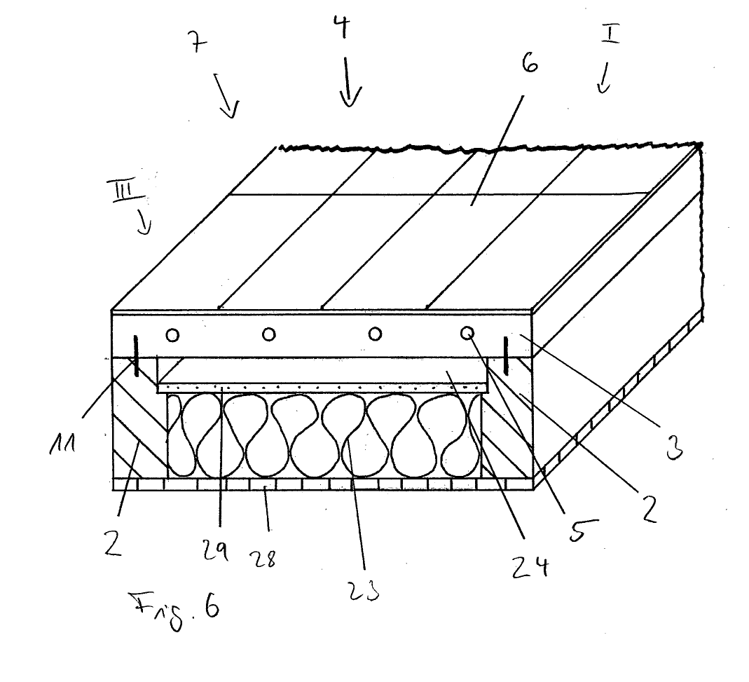

FIG. 6 a component according to the invention with a wood-concrete element.

FIG. 1 shows as an example a component with a composite element 1 comprising a concrete element 3 which is connected, for example, by a mechanical push link in the form of screws push-firmly with a wood element 2. On a solar-facing side 7 of the concrete element 3 a photo-voltaic element 6 is raised. On the photo-voltaic element 6 water can be routed by a water-routing side. Inside of the concrete element 3 wirings 13 of the solar heat elements 5 are embedded. The component can be in this implementation, for example, advantageously used as a noise barrier, as a flat roof or a car port.

FIG. 2 shows exemplarily a component consisting of an outmost concrete element 8 which is connected by a connection 11 in the form of a push link, for example, in the form of stuck sticks at least in a few points—push-stiffly—with the wood element 2. On the solar-facing side 7 of the concrete element 3 a photo-voltaic element 6 is fixed, which delivers at the same time the water-routing side for routing rainwater. Inside of the concrete element 3 wirings 13 are embedded for the media-leading solar heat element 5. The inner concrete element 9 is exemplarily by push link in the form of stuck streaking metals or perforated plates push-firmly connected with the wooden element 2. Inside of the inner concrete element 9 wirings 14 are embedded for the building cooling or the heating of the wall or covers. Between the two concrete elements 3 a hollow cavity between the wooden elements 2 is filled with insulation 12 in the form of insulating material in loose form or form-solidly to generate a climatic barrier between outside air and inside air. Depending on the kind and implementation of the insulation building covers can be generated, without appreciable warmth losses/energy losses. The component in this implementation can be used as a building wall, as a sloping roof or as a flat roof.

FIG. 3 shows exemplarily a component consisting of a stooped concrete element 3 which is connected by exemplary push links in the form of stuck plastic grids push-firmly with the stooped wooden element 2. On the solar-facing side 7 of the concrete element 3 a photo-voltaic element 6 is fixed. Inside of the concrete element 3 wirings 13 are embedded for the media-leading solar heat element 5. In this implementation the component can be used as one of many other components in a solar park in particular for applications in southern countries, e.g., PV foils in southern Spain, because of the additional cooling. In this manner cheap and easily arrangable fields for power production can be build, where it is possible to abstain more or less from expensive steel, which is heating.

FIG. 4 shows exemplarily a component with a wood-wood-composite element 1″. On a first wooden element 2 two further wooden elements 3″, for example profiled layering woods, are connected therewith, for example glued, that a zone 20 is build, in which on an insulation 23 a heat conducting fill 22 is applied, in which solar heat elements 5 are integrated. The zone 20 is limited by a coverage 25 with photovoltaic elements 6 in relation to the solar facing side 7, whereas the photovoltaic element 6 is especially held by the wooden elements 3″. The photovoltaic element 6 can be built, that light partially penetrates the photovoltaic element 6 to the heat conducting filling around the solar heat elements 5. Additionally the heat of the light can be conducted through the photovoltaic elements 6 and can be absorbed by the solar heat elements 5 in the zone 20. In this case the photovoltaic element 6 can be integrated into the glass plate as a thin film element. In a further not shown example of the invention a heating up of the conduction line can be made without a heat conducting substance directly by the solar radiation.

On a photovoltaic element 6 water can be drain off by a water conducting plane. Between the wooden element 2, the wooden elements 3″ and the photovoltaic element 6 a zone 20 is defined, which is at least partially filled with fiber-reinforced mud. In the inner part of the mud conducting lines of the solar heat element 5a embedded. The component in this example can be for example a light wood-composite solar heat element for restoration of existing buildings, especially for roofs. In this way the existing basic fabric can be refitted energetically without a rising of the load.

FIG. 5a shows a component according to the invention with a wooden element 2 and two metal and/or plastics elements 3″, especially as U-formed profile sections, which can be connected for example by gluing and/or screwing with a wooden element 2. Between the wooden element 2 and the metal and/or plastics elements 3″ a zone 20 is defined, into which solar heat elements 5 are integrated. The zone 20 is covered by a coverage 25, which has substantially solar voltaic elements 6. Herethrough light can be conducted in the case of a partial coverage or a thin layer coverage, is shown in FIG. 5b. At least heat is conducted through the photovoltaic element 6 and is sent onto the solar heat elements 5. On the photovoltaic elements 6 water can be drain off. The impermeability against water can be made by linking profiles 26 for instance, which seal the wood-composite elements circumferentially, for example shown as a UV-resistant rubber. Between the wooden element 2 and the metal and/or plastic elements 3″ and the photovoltaic element 6 a zone 20 is defined, in which conducting lines of the solar heat element 6 are arranged. On the wooden element 2 a reflection plane 27 can be arranged, which amplifies the heat intensity of the solar light to a higher degree of efficiency of the solar heat element 5. The component in this example can use light energy producing wood-metal and/or plastic element-composite elements for building coverings and/or solar plants, especially for producing current and heat.

FIG. 5b shows a component according to the invention with a metal and/or plastic element, whereas the covering 25 is covered only partially with photovoltaic elements 6, so that some parts a made for better light transparency.

FIG. 6 shows a component according to the invention with a wood-concrete composite element 1. Wooden elements 2 a connected with a concrete element 3, for example as a plastic fiber reinforced light concrete implementation, which is connected for example with gluing and/or mechanical connection 11, especially screwing, with the wooden elements 2. In the heat conducting concrete element 3 solar heat elements are integrated. On a light facing side 7 of the concrete a photovoltaic element 6 is arranged. On the photovoltaic element 6 water can be drain off through a water conducting plane. The wooden elements 2 can define a ventilation space 24 together with a first plate 29, especially a wooden working plate. Furthermore a second plate 28, especially a wooden soft fiber plate, can be used, whereas the resulting space 30 can be filled with an insulation 23. The space 24 allows a ventilation between the plate 29 and the heat conducting photovoltaic element 6.

The component of this example can be used for example as a roof and/or facade element in a new building and/or as en energetically renovation for buildings

### REFERENCES

1″ wood-concrete-composite element

1″ wood-wood-composite element

1″′ wood-metall and/or plastic-composite element

2 wood element

III retainer means

3 concrete element

3″ wood element

3′″ metal and/or plastic bar

4 solar element

5 solar heat element

6 photovoltaic element

7 side

8 outmost concrete element

9 inner concrete element

10 cooling element

11 connection

12 insulation

13 wiring

14 wiring

20 zone

21 side

22 means

23 insulation

24 area of ventilation

25 covering

26 linking profile

27 reflexion blank

28 plate

29 plate

1. A component for construction, said component comprising at least one wood-concrete composite element comprising at least one wood element and one concrete element, the wood element and the concrete element being connected together non-positively engaged and form-fitting and in an integrally bonding manner, especially the wood element and the concrete element are at least partially connected by thrust force, whereas at least one solar element, especially a solar heat element, is integrated into the concrete element and a photovoltaic element is arranged on a side of the concrete element facing the light.

2. The component of claim 1, characterized by that the wood-concrete composite element comprises the wood element and at least two concrete elements, whereas the wood element is connected as an intermediate element non-positively engaged and form-fitting and in an integrally bonding manner with both concrete elements and at least one solar heat element is integrated into the concrete element, which is outermost with regard to the light irradiation direction and a chill element is integrated into the inner concrete element.

3. The component of claim 1, characterized by that the wood-concrete composite element comprises at least two wood elements and an intervening concrete element, whereas comprising in between a non-positively engaged and form-fitting and in an integrally bonding manner connection between the wood elements and the concrete element.

4. The component of claim 3, characterized by that the connection comprises a geometrical form-fitting and mechanical connecting means and glue connection, in particular with sticks, pipes, grids, tins and nets and a surface bonded joint and a welding connection and a concrete grouting, whereas the connection especially is a push-firm connection, in particular by mechanical connecting means, in particular by nails, screws and brads.

5. The component of claim 1 4, characterized by that the wood-concrete composite elements are at least partially prefabricated and are brought together in the plant and on the building site.

6. The component of claim 1, characterized by that the wood elements comprise one-piece cross sections, in particular in the form of beams, chevrons, binders, panels, discs, planks and multi partial cross sections, in particular skeleton framings, triangle bar carriers, I-form beams, T-form carriers, case carriers and ligament panels.

7. The component of claim 1, characterized by that the concrete elements comprise one-piece cross sections in particular in form of beams, bearings, panels, discs and multi partial cross sections, in particular in the form of TT-bearings, I-bearings, T-bearings, case bearings, ligament panels, and π panels.

8. The component of claim 1, characterized by that the wood-concrete composite element is provided with damming up, isolating, protecting and dressing materials and introduced in particular between wood elements, insulations and installations in the plane and on the building site, so that there is one thermal isolation to the concrete, in particular with an inside-recumbent, final wall element, in particular as a steam barrier, in particular from plaster boards.

9-10. (canceled)

11. The component of claim 1, characterized in that the connection between the wood element and the retainer element has a geometric form fitting and or a mechanical connection means and a glue connection, especially with bars, tubes, lattices and grids and a surface bonded joint and a welding connection and concrete casting, whereas the connection is especially a push-firm connection, in particular by mechanical connecting means, in particular by nails, screws and brads.

12. The component of claim 1, characterized in that the wood-concrete composite elements are at least partially prefabricated and are brought together in the plant and on the building site.

13. The component of claim 1, characterized in that the wood elements comprise one-piece cross sections, in particular in the form of beams, chevrons, binders, panels, discs, planks and multi partial cross sections, in particular skeleton framings, triangle bar carriers, I-form beams, T-form carriers, case carriers and ligament panels.

14. The component of claim 1, characterized in that the concrete elements comprise one-piece cross sections in particular in form of beams, bearings, panels, discs and multi partial cross sections, in particular in the form of TT-bearings, I-bearings, T-bearings, case bearings, ligament panels, and π panels.

15. The component of claim 1, characterized in that the wood-concrete composite element is provided with damming up, isolating, protecting and dressing materials and introduced in particular between wood elements, insulations and installations in the plane and on the building site, so that this offers a thermal isolation to the concrete, in particular with an inside-recumbent, final wall element, in particular as a steam barrier, in particular from plaster boards.

16. The component of claim 1, characterized in that a wood-retainer means-composite element has at least one wood-wood-composite element, with at least a first wood element and a second wood element substantially in the form of a connection rob, which is applied on the first wood element and which defines at least partially a hollow space together with the first wood element, the hollow space is coated with a solar element, especially a solar heat element.

17. The component of claim 16, characterized in that the wood-retainer means-composite element has at least a wood-metal and plastics-composite element, with at least one wood element and a metal and plastics bar, which is provided on the wood element and together with the wood element defines at least partially a zone, which is coated with a solar element, especially a solar heat element.

18. The component of claim 1, for constructions like buildings, apartment houses, trade constructions, industrial constructions, sports facilities, factories, parking houses, stadiums, towers, bridges, noise barriers, car ports, in particular for building coverings, roofs, walls, and facades.

19. The component of claim 17, for constructions like stand-alone solar arrangements, in particular in solar parks, in particular in stooped in particular parabolic form of the wood-retainer means-composite elements.
